(19) United States
(12) Patent Application Publication
(10) Pub. No.: US 2026/0150570 A1
(43) Pub. Date: May 28, 2026

(54) DISPLAY DEVICE

(71) Applicant: LG DISPLAY CO., LTD., SEOUL (KR)

(72) Inventors: Jungmin Yoon, Paju-si (KR); Wonjin Choi, Paju-si (KR); Yong-Ku Lee, Paju-si (KR); Seungcheol You, Paju-si (KR)

(21) Appl. No.: 19/334,295

(22) Filed: Sep. 19, 2025

(30) Foreign Application Priority Data
Nov. 27, 2024 (KR) 10-2024-0171742

(51) Int. Cl. H10K 59/80; H10K 59/122

(52) U.S. Cl. CPC H10K 59/8792; H10K 59/122; H10K 59/879

(57) ABSTRACT

A display device includes a substrate, a first light emitting element disposed on the substrate, a second light emitting element disposed on the substrate and adjacent to the first light emitting element, an encapsulation layer disposed on the first light emitting element and the second light emitting element, a planarization layer disposed on the encapsulation layer, a black matrix disposed on the planarization layer and including a first opening and a second opening corresponding to the first and second light emitting elements respectively, and a partition wall overlapping the black matrix and disposed on a side surface of at least one of the encapsulation layer or the planarization layer.

### CROSS-REFERENCE TO RELATED APPLICATION

Pursuant to 35 U.S.C. § 119(a), this application claims an earlier filing date and right of priority to Korean Patent Application No. 10-2024-0171742, filed in the Republic of Korea on Nov. 27, 2024, the contents of which are hereby incorporated by reference in their entirety.

### TECHNICAL FIELD

This disclosure generally relates to a display device.

### BACKGROUND

There has been increased demand for various types of display devices for displaying images. For example, display devices are included in various electronic devices, such as smartphones, digital cameras, laptop computers, navigation systems, and smart televisions.

### SUMMARY

A display device according to embodiments of the disclosure may comprise a substrate, a first light emitting element disposed on the substrate, a second light emitting element disposed on the substrate and adjacent to the first light emitting element, and an encapsulation layer disposed on the first light emitting element and the second light emitting element.

The display device according to implementations of the disclosure may comprise a planarization layer disposed on the encapsulation layer and a black matrix disposed on the planarization layer and including a first opening and a second opening.

The display device according to implementations of the disclosure may comprise a first lens disposed between the encapsulation layer and the planarization layer and overlapping the first opening.

The display device according to implementations of the disclosure may comprise a second lens disposed between the encapsulation layer and the planarization layer and overlapping the second opening corresponding to the first and second light emitting elements respectively.

The display device according to implementations of the disclosure may comprise a first color filter disposed on the black matrix and overlapping the first opening and a second color filter disposed on the black matrix and overlapping the second opening.

The display device according to implementations of the disclosure may comprise a partition wall overlapping the black matrix and disposed on a side surface of at least one of the encapsulation layer or the planarization layer.

In another aspect, a display device according to implementations of the disclosure may comprise a substrate, a first light emitting element disposed on the substrate, a second light emitting element disposed on the substrate and adjacent to the first light emitting element, and a bank disposed between the first light emitting element and the second light emitting element.

The display device according to implementations of the disclosure may comprise a black matrix disposed on the first light emitting element and the second light emitting element and including a first opening and a second opening.

The display device according to implementations of the disclosure may comprise a first color filter disposed on the black matrix and overlapping the first opening and a second color filter disposed on the black matrix and overlapping the second opening.

The display device according to implementations of the disclosure may comprise a first convex portion disposed between the first light emitting element and the first color filter, overlapping the first opening, and having a convex upper surface.

The display device according to implementations of the disclosure may comprise a second convex portion disposed between the second light emitting element and the second color filter, overlapping the second opening, and having a convex upper surface.

The display device according to implementations of the disclosure may comprise an organic partition wall disposed between the bank and the black matrix and including an organic material.

Additional features and aspects of the disclosure are set forth in part in the description that follows and in part will become apparent from the description or may be learned by practice of the disclosure provided herein. Other features and aspects of the disclosure may be realized and attained by the structures pointed out in the present disclosure, or derivable therefrom, and the claims hereof as well as the appended drawings.

According to implementations of the disclosure, there may be provided a display device having a structure capable of implementing the desired viewing angle characteristics through a partition wall structure.

According to implementations of the disclosure, there may be provided a display device having a structure that facilitates the implementation of the desired viewing angle characteristics through a lens structure.

According to implementations of the disclosure, there may be provided a display device having a structure capable of implementing viewing angle characteristics in the display panel without attaching a separate film for implementing the desired viewing angle characteristics to the display panel.

According to implementations of the disclosure, it may be possible to control the viewing angle characteristics in the desired form without a film attachment process, enabling process optimization.

According to implementations of the disclosure, as the desired viewing angle characteristics may be achieved without an external film, the flexibility of the display panel may be enhanced, and the thickness may be decreased.

It is to be understood that both the foregoing general description and the following detailed description are exemplary and explanatory and are intended to provide further explanation of the disclosure as claimed.

### DESCRIPTION OF DRAWINGS

The accompanying drawings, that may be included to provide a further understanding of the disclosure and may be incorporated in and constitute a part of the disclosure, illustrate implementations of the disclosure and together with the description serve to explain various principles of the disclosure.

FIG. 1 is a diagram illustrating a system configuration of a display device according to example implementations of the disclosure.

FIG. 2 illustrates a display device according to example implementations of the disclosure.

FIG. 3 is a cross-sectional view illustrating a display panel according to example implementations of the disclosure.

FIG. 4 is a plan view illustrating a display panel according to example implementations of the disclosure.

FIGS. 5 to 12 are diagrams illustrating a cross-sectional structure of a display panel according to example implementations of the disclosure.

FIGS. 13 to 16 are diagrams illustrating an upper partition wall structure and a lower partition wall structure of a display panel according to example implementations of the disclosure.

FIG. 17 is an illustration of an example of the spectrum according to the wavelength band according to example implementations of the disclosure.

FIG. 18 is an illustration of an example of the spectrum according to the application of a first partition wall according to example implementations of the disclosure.

FIG. 19 is an illustration of an example of the optical spectrum before and after the application of a first partition wall according to example implementations of the disclosure.

FIG. 20 is an illustration of an example of the cut-off ratio according to the viewing angle before and after the application of a first partition wall according to example implementations of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

When included in an electronic device, a display device may be expected to satisfy a desired level of viewing angle according to the product type or use case of the electronic device. However, for various reasons, there is considerable difficulty in implementing the desired level of viewing angle.

Implementations of the present disclosure provide a display device having a structure capable of implementing desired viewing angle characteristics.

Implementations of the disclosure provide a display device having a structure capable of implementing viewing angle characteristics in the display panel without attaching a separate film for implementing the desired viewing angle characteristics to the display panel.

In the following description of examples or implementations of the disclosure, reference will be made to the accompanying drawings in which it is shown by way of illustration specific examples or implementations that can be implemented, and in which the same reference numerals and signs can be used to designate the same or like components even when they are shown in different accompanying drawings from one another. Further, in the following description of examples or implementations of the disclosure, detailed descriptions of well-known functions and components incorporated herein will be omitted when it is determined that the description may make the subject matter in some implementations of the disclosure rather unclear. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through following example implementations described with reference to the accompanying drawings. The present disclosure may, however, be implemented in different forms and should not be construed as limited to the example implementations set forth herein. Rather, these example implementations may be provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example implementations of the present disclosure are merely given by way of example. Therefore, the present disclosure is not limited to the illustrations in the drawings. The same or similar elements are designated by the same reference numerals throughout the specification unless otherwise specified. Any implementation described herein as an “example” is not necessarily to be construed as preferred or advantageous over other implementations.

The terms such as “including”, “having”, “containing”, “constituting” “make up of”, and “formed of” used herein are generally intended to allow other components to be added unless the terms are used with a more limiting term, such as “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless a more limiting term, such as “directly” or “immediately” is used together.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Features of various implementations of the present disclosure may be partially or overall coupled to or combined with each other, and may be variously inter-operated with each other and driven technically as those skilled in the art can sufficiently understand. Implementations of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example implementations of the disclosure are described in detail with reference to the accompanying drawings. Further, all the components of each display device according to all implementations of the present disclosure are operatively coupled and configured. For convenience of description, a scale of each of elements illustrated in the accompanying drawings differs from a real scale, and thus, is not limited to a scale illustrated in the drawings.

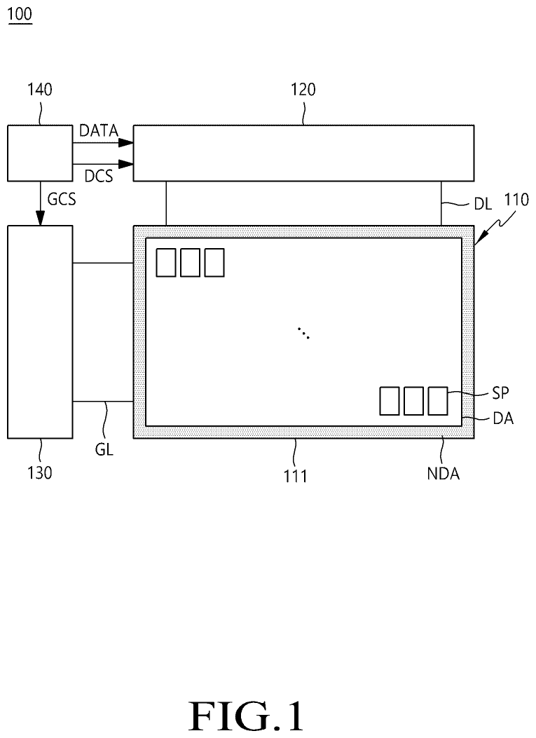

FIG. 1 is a diagram illustrating a system configuration of a display device 100 according to example implementations of the disclosure.

Referring to FIG. 1, a display device 100 according to implementations of the disclosure may include a display panel 110 and display driving circuits, as components for displaying images. The display driving circuit may be a circuit for driving the display panel 110. The display driving circuits may include one or more of a data driving circuit 120, a gate driving circuit 130, and a controller 140, but implementations of the disclosure are not limited thereto.

The display panel 110 may include a substrate 111 and a plurality of subpixels SP disposed on the substrate 111.

The substrate 111 may include a display area DA and a non-display area NDA adjacent to the display area DA.

The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may also be referred to as a bezel (or bezel area). The non-display area NDA may include a pad area.

For example, the non-display area NDA may include a first non-display area, a second non-display area, a third non-display area, and a fourth non-display area. The first non-display area may be positioned outside the display area DA in the row direction. The second non-display area may be positioned outside the display area DA in the row direction and may be positioned opposite to the first non-display area. The third non-display area may be positioned outside the display area DA in the column direction. The fourth non-display area may be positioned outside the display area DA in the column direction and may be positioned opposite to the third non-display area.

Among the first to fourth non-display areas, the fourth non-display area may include a pad area where a driving circuit is connected, bonded (or attached), and the first to third non-display areas may have a very small size, but the implementations of the disclosure are not limited thereto.

As another example, a portion of the non-display area NDA which is adjacent to the display area DA and also referred to as the boundary area or bend area may be bent so that the non-display area NDA may be positioned under the display area.

No or little change may be made to the non-display area NDA shown to the user when the user views the display device 100 from the front, but implementations of the disclosure are not limited thereto.

The display device 100 according to implementations of the disclosure may be a self-luminous display device in which the display panel 110 emits light by itself, but implementations of the disclosure are not limited thereto. When the display device 100 according to the implementations of the disclosure is a self-emission display device, each of the plurality of subpixels SP may include a light emitting element.

For example, the display device 100 according to implementations of the disclosure may be an organic light emitting diode display in which the light emitting element is implemented as an organic light emitting diode (OLED). As another example, the display device 100 according to implementations of the disclosure may be an inorganic light emitting display device in which the light emitting element is implemented as an inorganic material-based light emitting diode. As another example, the display device 100 according to implementations of the disclosure may be a quantum dot display device in which the light emitting element is implemented as a quantum dot which is self-emission semiconductor crystal. As another example, the display device 100 according to implementations of the disclosure may be a micro LED display device or a mini LED display device.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but implementations of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., a row direction or column direction). Each of the plurality of data lines DL may be disposed to extend in a second direction (e.g., a column direction or row direction) different from the first direction.

According to implementations of the disclosure, e.g., the first direction may be the row direction, and the second direction may be the column direction. As another example, the first direction may be the column direction, and the second direction may be the row direction. The row direction and the column direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but implementations of the disclosure are not limited thereto. In implementations of the disclosure, the angle between the first direction and the second direction may be 90 degrees or may an angle different from 90 degrees.

The data driving circuit 120 may be a circuit for driving the plurality of data lines DL, and may output data signals to the plurality of data lines DL.

The data driving circuit 120 may receive digital image data DATA from the controller 140 and may convert the received image data DATA into analog data signals (or also referred to as data voltages) and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but implementations of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to implementations of the disclosure, the gate driving circuit 130 may be embedded, in a gate in panel (GIP) type, in the display panel 110, but implementations of the disclosure are not limited thereto. When the gate driving circuit 130 is of the gate in panel type, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-display area NDA of the display panel 110. As another example, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA). As another example, the gate driving circuit 130 may be disposed over the entire display area DA.

When the gate driving circuit 130 is disposed in the display area DA of the display panel 110, the gate driving circuit 130 may vertically overlap the subpixels SP disposed in the display area DA. For example, the gate driving circuit 130 may vertically overlap the light emitting elements and transistors included in the disposed subpixels SP in the display area DA. The gate driving circuit 130 may vertically overlap a plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be, but is not limited to, a semiconductor layer.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI), and a serial peripheral interface (SPI), but implementations of the disclosure are not limited thereto.

The display device 100 according to implementations of the disclosure may provide not only an image display function, but also a touch sensing function of detecting whether a touch is made by a touch object, such as a finger or a pen, or detecting the position of a touch.

The display device 100 according to implementations of the disclosure may be a mobile terminal, such as a smart phone or a tablet, displays for vehicles or VR, or a monitor or television (TV) of various sizes but, without limited thereto, may be a display in various types and various sizes capable of displaying information or images.

The display device 100 according to implementations of the disclosure may include an electronic device such as a camera (image sensor), a detection sensor, or the like. For example, the detection sensor may be a sensor that detects an object or a human body by receiving light such as infrared rays, ultrasonic waves, or ultraviolet rays, but implementations of the disclosure are not limited thereto.

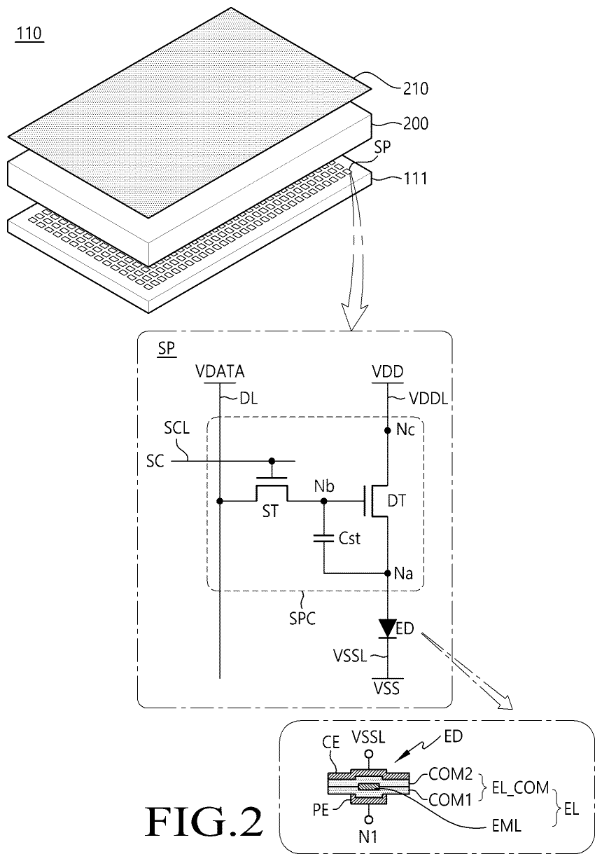

FIG. 2 illustrates a display panel 110 according to an implementation of the disclosure.

Referring to FIG. 2, the display panel 110 according to implementations of the disclosure may include a substrate 111 disposed in a plurality of subpixels SP, an encapsulation layer 200 on the substrate 111, and a color filter layer 210 on the encapsulation layer 200. The encapsulation layer 200 may also be referred to as an encapsulation substrate or an encapsulation unit.

Referring to FIG. 2, when the display device 100 according to implementations of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but implementations of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed across the plurality of subpixels SP, but implementations of the disclosure are not limited thereto.

In other words, the light emitting layer EML may be disposed for each emission area or disposed commonly across a plurality of emission areas. The common intermediate layer EL_COM may be commonly disposed across a plurality of emission areas and non-emission areas, but implementations of the disclosure are not limited thereto.

For example, the first common intermediate layer COM1 may include a hole injection layer HIL, an electron blocking layer EBL, and a hole transport layer HTL, but implementations of the disclosure are not limited thereto. The second common intermediate layer COM2 may include an electron transport layer ETL, a hole blocking layer HBL, and an electron injection layer EIL, but implementations of the disclosure are not limited thereto.

The hole injection layer HIL may inject holes from the pixel electrode PE to the hole transport layer HTL, and the hole transport layer HTL may transport holes to the light emitting layer EML. The electron injection layer EIL may inject electrons from the common electrode CE to the electron transport layer ETL, and the electron transport layer ETL may transport electrons to the light emitting layer EML.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node Na of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), a quantum dot light emitting element, a micro LED, or a mini LED, but implementations of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal VDATA, and the third node Nc may receive a driving voltage VDD, which is another kind of common voltage, from the driving voltage line VDDL. The driving transistor DT may be connected on the first node Na and the third node Nc. In the disclosure, “driving voltage VDD” may also be referred to as a second common voltage, a high-potential power voltage, or a high-potential voltage, and “driving voltage line VDDL” may also be referred to as a second common voltage line, a low-potential power voltage line, or a low-potential voltage line.

In the driving transistor DT, the second node Nb may be a gate node, the first node Na may be a source node or a drain node, and the third node Nc may be a drain node or a source node. Hereinafter, for convenience of description, an example is described in which in the driving transistor DT, the second node Nb may be a gate node, the first node Na may be a source node, and the third node Nc may be a drain node, but implementations of the disclosure are not limited thereto.

The scan transistor ST included in the subpixel circuit SPC illustrated in FIG. 2 may be a switching transistor for transferring the data signal VDATA, which is an image signal, to the second node Nb, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The capacitor Cst may be an external capacitor configured to be outside the driving transistor DT, but not a parasite capacitor (e.g., Cgs or Cgd) which is an internal capacitor that may be present between the first node Na and the second node Nb of the driving transistor DT, but implementations of the disclosure are not limited thereto.

Each of the driving transistor DT and the scan transistor ST may be an n-type transistor or a p-type transistor, but implementations of the disclosure are not limited thereto. For example, one of the driving transistor DT and the scan transistor ST may be either an n-type transistor or a p-type transistor.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

As illustrated in FIG. 2, the subpixel circuit SPC may have a 2T (Transistor)1 C (Capacitor) structure including two transistors DT and ST and one capacitor Cst. In some cases, the subpixel circuit SPC may include one or more transistors or may include one or more capacitors, but implementations of the disclosure are not limited thereto.

For example, the subpixel circuit SPC may have a 3T1C structure including 3 transistors and 1 capacitor. For example, the subpixel circuit SPC may have a 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor, but implementations of the disclosure are not limited thereto.

Depending on the structure of the subpixel circuit SPC, the type and number of gate lines or the gate signals supplied to the subpixel SP may vary. Further, the type and the number of common driving signals supplied to the subpixel SP may vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent or reduce external moisture or oxygen from penetrating into circuit elements (e.g., the light emitting element ED). The encapsulation layer 200 may be configured in various forms so that the light emitting elements ED do not contact moisture or oxygen. For example, the encapsulation layer 200 may be constituted of two or more layers in which organic films and inorganic films are stacked in alternation, but implementations of the disclosure are not limited thereto.

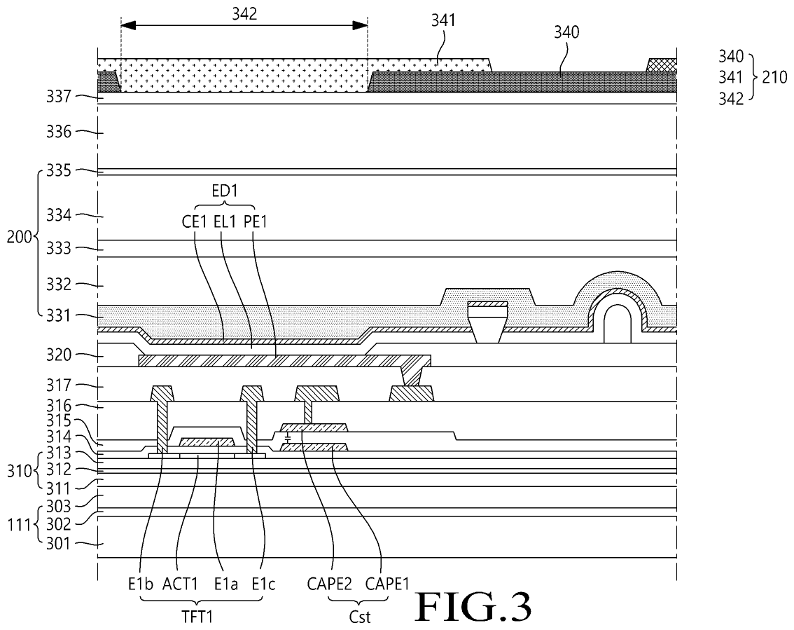

FIG. 3 is a cross-sectional view of a display panel 110 according to implementations of the disclosure.

Referring to FIG. 3, the display panel 110 according to implementations of the disclosure may include a substrate 111, a transistor unit, a light emitting element unit, and an encapsulation unit 200, but implementations of the disclosure are not limited thereto.

The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer, but implementations of the disclosure are not limited thereto. The intermediate substrate layer 302 may be an inorganic insulation layer, but implementations of the disclosure are not limited thereto. When an electric charge is charged to the first substrate PI1 which is a polyimide layer, the intermediate substrate layer 302 may prevent or reduce the electric charge from affecting transistors disposed on the second substrate 303 through the second substrate 303 which is a polyimide layer.

Further, the intermediate substrate layer 302 may prevent or reduce a moisture component from penetrating upward through the first substrate 301. For example, the intermediate substrate layer 302 may be formed of a single layer of silicon nitride (SiNₓ) or silicon oxide (SiOₓ) or multiple layers thereof, or may be formed of a double layer of silicon oxide (SiOₓ) and silicon nitride (SiNₓ), but is not limited thereto.

The transistor unit may include insulation layers 311, 312, 313, 314, 315, and 316 on the substrate 111, a thin film transistor TFT1, a storage capacitor Cst, and various electrodes or signal lines.

The transistor unit may include a first thin film transistor TFT1.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but implementations of the disclosure are not limited thereto.

The first active layer ACT1 may include a first semiconductor material. For example, the first semiconductor material may include an oxide semiconductor, amorphous silicon, polysilicon, or low temperature polysilicon (LTPS), but implementations of the disclosure are not limited thereto. The first thin film transistor TFT1 may be implemented as a p-channel transistor or an n-channel thin film transistor, but implementations of the disclosure are not limited thereto.

The first active layer ACT1 of the first thin film transistor TFT1 may have the following types of semiconductor materials.

For example, the first active layer ACT1 of the first thin film transistor TFT1 may include an oxide semiconductor material. As another example, the first active layer ACT1 of the first thin film transistor TFT1 may include a low-temperature polysilicon semiconductor material.

The transistors in the display area DA may be operated as follows.

For example, at least one transistor of in each subpixel SP may be implemented as the first thin film transistor TFT1.

For example, in each subpixel SP, the driving transistor DT may be implemented as the first thin film transistor TFT1.

In the subpixel circuit SPC, the first light emitting element ED1 may be connected to the transistor. The first pixel electrode PE1 of the first light emitting element ED1 may be connected to the source electrode or drain electrode of the transistor. The transistor connected to the first light emitting element ED1 may be the first thin film transistor TFT1 of FIG. 3 or another transistor. According to the example of FIG. 2, the transistor connected to the first light emitting element ED1 may be the driving transistor DT or may be another transistor (e.g., an emission control transistor) connected between the driving transistor DT and the first light emitting element ED1. Implementations of the disclosure are not limited thereto.

The transistors in the non-display area NDA may be operated as follows.

For example, the active layers of the transistors included in the gate-in-panel (GIP) type gate driving circuit 130 may be formed of an oxide semiconductor material. As another example, the active layers of the transistors included in the gate-in-panel (GIP) type gate driving circuit 130 may be formed of a low-temperature polysilicon semiconductor material. As another example, among the transistors included in the gate-in-panel (GIP) type gate driving circuit 130, some active layers may be formed of a low-temperature polysilicon semiconductor material, and other active layers may be formed of an oxide semiconductor material.

A buffer layer 310 may be disposed under the first active layer ACT1 of the first thin film transistor TFT1. For example, the first active layer ACT1 of the first thin film transistor TFT1 may be positioned on the buffer layer 310. Implementations of the disclosure are not limited thereto.

The storage capacitor Cst may be disposed in various metal layers in the display panel 110. For example, the storage capacitor Cst may include a first capacitor electrode CAPE1 and a second capacitor CAPE2. For example, one of the first capacitor electrode CAPE1 and the second capacitor CAPE2 may be electrically connected to the source electrode of the driving transistor DT, and the other may be electrically connected to the gate electrode of the driving transistor DT.

The light emitting element unit may include a plurality of light emitting elements ED. Each of the light emitting elements ED may include a pixel electrode PE, an intermediate layer EL, and a common electrode CE. For example, the first light emitting element ED1 disposed on the first planarization layer 317 may be included. The first light emitting element ED1 may include a first pixel electrode PE1, a first intermediate layer EL1, and a first common electrode CE1.

The encapsulation unit may include an encapsulation layer 200 on the plurality of light emitting elements ED. The encapsulation layer 200 may be a single layer or multiple layers, but implementations of the disclosure are not limited thereto.

Hereinafter, a structure or a vertical structure of the display panel 110 according to implementations of the disclosure is described in more detail with reference to FIG. 3.

Referring to FIG. 3, a buffer layer 310 may be disposed on a substrate 111. The buffer layer 310 may be a single layer or multiple layers, but implementations of the disclosure are not limited thereto. When the buffer layer 310 is multiple layers, the buffer layer 310 may include a lower buffer layer 311, an intermediate buffer layer 312, and an upper buffer layer 313.

The first active layer ACT1 of the first thin film transistor TFT1 may be disposed on the buffer layer 310. The first active layer ACT1 may include a channel area in which a channel is formed, a source connection area on one side of the channel area, and a drain connection area on the other side of the channel area.

The first gate insulation layer 314 may be disposed on the first active layer ACT1 of the first thin film transistor TFT1. The first gate electrode E1a of the first thin film transistor TFT1 may be disposed on the first gate insulation layer 314. The first inter-layer insulation layer 315 may be disposed on the first gate electrode E1a of the first thin film transistor TFT1. Here, the metal layer where the first gate electrode E1a of the first thin film transistor TFT1 is disposed may be referred to as a gate metal layer.

The first source electrode E1b and the first drain electrode E1c of the first thin film transistor TFT1 may be disposed on the second interlayer insulation film 316.

The first source electrode E1b and the first drain electrode E1c of the first thin film transistor TFT1 may be connected to the source connection area and the drain connection area, respectively, of the first active layer ACT1 through holes of the second interlayer insulation layer 316, the first interlayer insulation layer 315, and the first gate insulation layer 314.

The first source electrode E1b and the first drain electrode E1c of the first thin film transistor TFT1 may include a first source-drain metal, and be disposed in the first source-drain metal layer.

Referring to FIG. 3, e.g., the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first gate insulation layer 314 and may be disposed in the first gate metal layer, but implementations of the disclosure are not limited thereto. For example, the second capacitor electrode CAPE2 may be disposed on the first inter-layer insulation layer 315. Implementations of the disclosure are not limited thereto.

The first planarization layer 317 may be disposed on the first thin film transistor TFT1 and may be disposed under the light emitting element ED. The first planarization layer 317 may be an organic insulation layer including an organic insulating material.

For example, the first planarization layer 317 may be constituted of one layer. As another example, the first planarization layer 317 may include two layers. As another example, the first planarization layer 317 may include three or more layers, but implementations of the disclosure are not limited thereto.

Referring to FIG. 3, the first planarization layer 317 may be disposed on the first source electrode E1b and the first drain electrode E1c of the first thin film transistor TFT1. For example, the first planarization layer 317 may be disposed on the first thin film transistor TFT1. For example, the first planarization layer 317 may be disposed to cover the entire first thin film transistor TFT1, but disclosure is not limited thereto.

Referring to FIG. 3, the light emitting element unit may be disposed on the first planarization layer 317. For example, the first light emitting element ED1 may be formed on the first planarization layer 317. The first light emitting element ED1 may include a first pixel electrode PE1, a first intermediate layer EL1, and a first common electrode CE1. The emission area of the first light emitting element ED1 may be formed in an area where the first pixel electrode PE1, the first intermediate layer EL1, and the first common electrode CE1 overlap and contact each other.

The bank 320 may be disposed on the first pixel electrode PE1. The opening of the bank 320 may expose a portion of the first pixel electrode PE1 to form the emission area. The opening of the bank 320 may overlap a portion of the first pixel electrode PE1.

For example, the bank 320 may be formed of a material including a black pigment, or an organic material such as a benzocyclobutene resin, a polyimide resin, an acrylic resin, or a photosensitive polymer, but implementations of the disclosure are not limited thereto. When the bank 320 is formed of a material including a black pigment, a black dye, or the like, it may be a black bank. When the bank 320 is formed of a material including a black pigment or a black dye, light from the outside may be blocked or light reflected from the outside may be blocked, and thus the luminance of the display device 100 may be enhanced.

The first intermediate layer EL1 of the first light emitting element ED1 may be disposed on a portion of the first pixel electrode PE1 and the bank 320. The first common electrode CE1 may be disposed on the first intermediate layer EL1.

Referring to FIG. 3, the encapsulation portion is disposed on the light emitting element portion and may be positioned on the first common electrode CE1. The encapsulation portion may include an encapsulation layer 200 formed on the first common electrode CE1.

The encapsulation layer 200 may prevent or reduce moisture or oxygen from penetrating into the first light emitting element ED1. For example, the encapsulation layer 200 may prevent or reduce moisture or oxygen from penetrating the organic material included in the first intermediate layer EL1 of the first light emitting element ED1. The encapsulation layer 200 may be formed of a single layer or multiple layers, but implementations of the disclosure are not limited thereto.

As an example, the encapsulation layer 200 may include a first inorganic layer 331, a first organic layer 332, a second inorganic layer 333, a second organic layer 334, and a third inorganic layer 335, but the implementations of the disclosure are not limited thereto. For example, although it is shown in FIG. 3 that the encapsulation layer 200 includes a structure in which three inorganic layers and two organic layers alternatively stacked on one another, but the implementations of the disclosure are not limited thereto, and various other structures such as two inorganic layers and one organic layer are alternatively stacked on one another are also possible.

For example, the first inorganic layer 331, the second inorganic layer 333, and the third inorganic layer 335 may include an inorganic encapsulation layer, and the first organic layer 332 and the second organic layer 334 may include an organic encapsulation layer, but the implementations of the disclosure are not limited thereto.

Referring to FIG. 3, a second planarization layer 336 may be disposed on the encapsulation layer 200. The second planarization layer 336 may be an organic insulation layer including an organic insulating material.

For example, the second planarization layer 336 may be composed of a single layer. As another example, a second planarization layer 336 may include two layers. As another example, the second planarization layer 336 may include three or more layers, but the implementations of the disclosure are not limited thereto.

Referring to FIG. 3, a fourth inorganic layer 337 may be disposed on the second planarization layer 336. The fourth inorganic layer 337 may be an inorganic insulation layer including an inorganic insulating material.

Referring to FIG. 3, a color filter layer 210 may be disposed on the fourth inorganic layer 337. The color filter layer 210 may include a black matrix 340, a first color filter 341, and a first opening 342.

The black matrix 340 may be disposed on a fourth inorganic layer 337 and may include the first opening 342.

For example, the black matrix 340 may be composed of a material including a black pigment or the like, or an organic material such as benzocyclobutene resin, polyimide resin, acrylic resin, or a photosensitive polymer, but the implementations of the disclosure are not limited thereto. When the black matrix 340 is composed of a material including a black pigment or a black dye, it may be a black bank. When the black matrix 340 is composed of a material including a black pigment or black dye, it may block light from outside or block light reflected from outside, and may reflect or absorb light leaking from the inside, thereby enhancing the brightness of the display device 100.

The first color filter 341 is disposed on the black matrix 340 and may overlap the first opening 342 and the first light emitting element ED1. The first color filter 341 may allow light of a predetermined wavelength band to pass through the first opening 342.

For example, the first color filter 341 disposed in an area corresponding to the first light emitting element ED1 may allow light of at least one wavelength band among red (R), green (G), and blue (B) emitted from the first light emitting element ED1 to pass through.

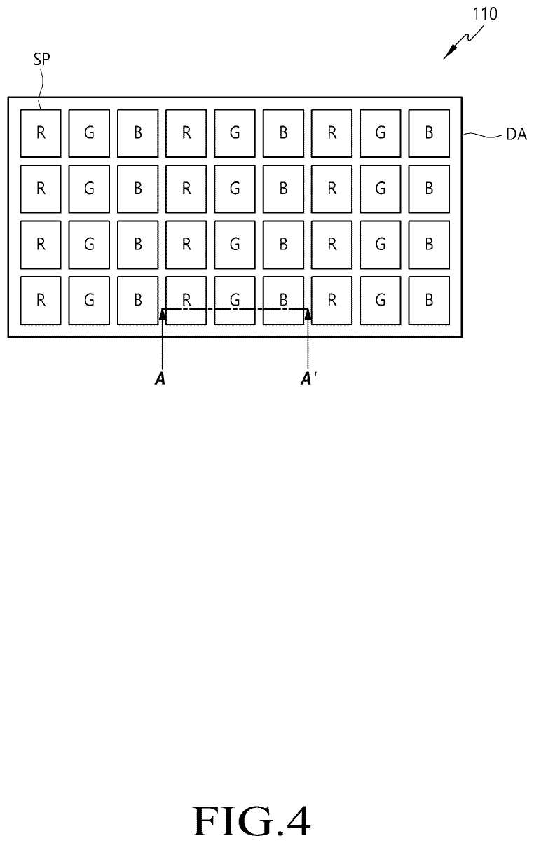

FIG. 4 is a plan view of a display panel 110 according to implementations of the disclosure.

Referring to FIG. 4, the display panel 110 according to implementations of the disclosure may include a plurality of subpixels SP. The subpixels SP may be disposed in a display area DA for displaying an image. Each subpixel SP may include a light emitting element provided with red (R), green (G), and blue (B).

In addition, for example, the display device 100 according to implementations of the disclosure may be a general TV or monitor device. As another example, the display device 100 according to implementations of the disclosure may be a smartphone, tablet, or wearable electronic device. As another example, in an implementation, the display device 100 according to implementations of the disclosure may be a vehicle display, a virtual reality (VR) electronic device, or an augmented reality (AR) electronic device.

In addition, the display panel 110 of the display device 100 according to implementations of the disclosure may have a structure (viewing angle characteristic enhancement structure) that implements desired viewing angle characteristics. Hereinafter, the viewing angle characteristic enhancement structure according to implementations of the disclosure is described in more detail.

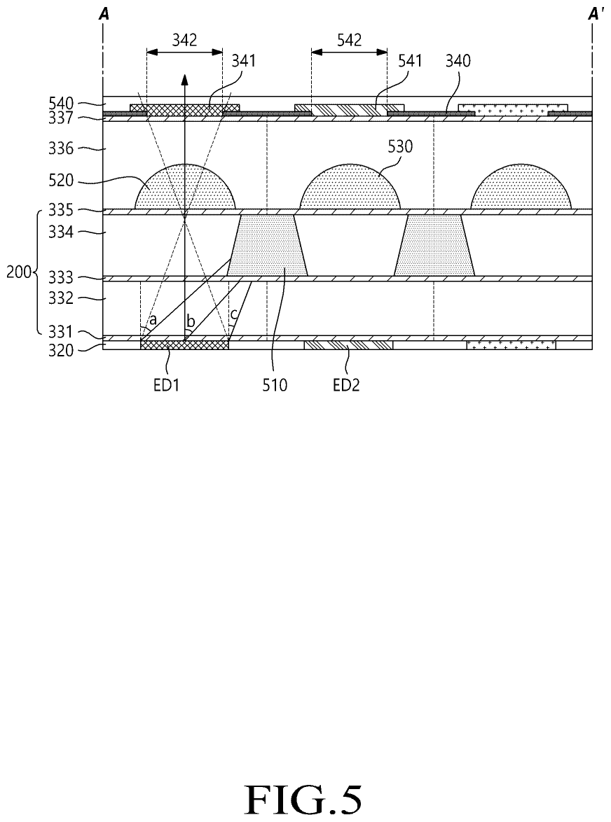

FIGS. 5 to 12 are diagrams illustrating a cross-sectional structure of a display panel 110 according to implementations of the disclosure. FIGS. 5 to 12 illustrate cross-sections taken along the cutting line A-A′ of FIG. 4.

Referring to FIGS. 5 to 12, the display panel according to implementations of the disclosure may include a first light emitting element ED1 disposed on a bank 320 and a second light emitting element ED2 adjacent to the first light emitting element ED1.

For example, the first light emitting element ED1 and the second light emitting element ED2 may be an organic light emitting diode (OLED), an inorganic material-based light emitting diode (LED), a quantum dot light emitting element, a micro LED, or a mini LED, but the implementations of the disclosure are not limited thereto.

The first light emitting element ED1 may emit first light including a first wavelength band, and the second light emitting element ED2 may emit second light including a second wavelength band. The wavelength band of the first light may include being shorter than the wavelength band of the second light, but the implementations of the disclosure are not limited thereto.

One of the first light and the second light may include one color among red (R), green (G), and blue (B), and the other of the first light and the second light may include another color among red (R), green (G), and blue (B). For example, if the first light includes blue (B) color light, the second light may include green (G) color light. As another example, if the first light includes blue (B) color light, the second light may include red (R) color light. As another example, if the first light includes green (G) color light, the second light may include red (R) color light, but the implementations of the disclosure are not limited thereto.

Referring to FIGS. 5 to 12, an encapsulation layer 200 may be disposed on the first light emitting element ED1 and the second light emitting element ED2. For example, the encapsulation layer 200 may prevent or reduce moisture or oxygen from penetrating into the first light emitting element ED1 and the second light emitting element ED2. The encapsulation layer 200 may be composed of a single layer or multiple layers, but the implementations of the disclosure are not limited thereto.

As an example, the encapsulation layer 200 may include a first inorganic layer 331, a first organic layer 332, a second inorganic layer 333, a second organic layer 334, and a third inorganic layer 335, but the implementations of the disclosure are not limited thereto.

For example, the first inorganic layer 331, the second inorganic layer 333, and the third inorganic layer 335 may include an inorganic encapsulation layer, and the first organic layer 332 and the second organic layer 334 may include an organic encapsulation layer, but the implementations of the disclosure are not limited thereto.

Referring to FIGS. 5 to 12, a second planarization layer 336 may be disposed on the encapsulation layer 200. The second planarization layer 336 may be an organic insulation layer including an organic insulating material, but the implementations of the disclosure are not limited thereto.

For example, the second planarization layer 336 may be composed of a single layer. As another example, a second planarization layer 336 may include two layers. As another example, the second planarization layer 336 may include three or more layers, but the implementations of the disclosure are not limited thereto.

Referring to FIGS. 5 to 12, a fourth inorganic layer 337 may be disposed on the second planarization layer 336. For example, the fourth inorganic layer 337 may be an inorganic insulation layer including an inorganic insulating material, but the implementations of the disclosure are not limited thereto.

Referring to FIGS. 5 to 12, a color filter layer 210 may be disposed on the fourth inorganic layer 337. The color filter layer 210 may include a black matrix 340, a first color filter 341, a second color filter 541, a first opening 342, a second opening 542, and a support layer 540.

The black matrix 340 may be disposed on the fourth inorganic layer 337 and may include a first opening 342 and a second opening 542.

For example, the black matrix 340 may be composed of a material including a black pigment or the like, or an organic material such as benzocyclobutene resin, polyimide resin, acrylic resin, or a photosensitive polymer, but the implementations of the disclosure are not limited thereto. When the black matrix 340 is composed of a material including a black pigment or a black dye, it may be a black bank. When the black matrix 340 is composed of a material including a black pigment or black dye, it may block light from outside or block light reflected from outside, and may reflect or absorb light leaking from the inside, thereby enhancing the brightness of the display device 100.

Referring to FIGS. 5 to 12, the first color filter 341 and the second color filter 541 may be disposed on the black matrix 340. The first color filter 341 may overlap the first opening 342 and a first light emitting element ED1, and the second color filter 541 may overlap the second opening 542 and a second light emitting element ED2.

The first color filter 341 may allow light of a predetermined wavelength band to pass through the first opening 342, and the second color filter 541 may allow light of a predetermined wavelength band to pass through the second opening 542.

For example, the first color filter 341 disposed in an area corresponding to the first light emitting element ED1 may allow light of at least one wavelength band among bands including red (R), green (G), and blue (B) emitted from the first light emitting element ED1 and the second light emitting element ED2 to pass through, and the second color filter 541 disposed in an area corresponding to the second light emitting element ED2 may allow light of at least one wavelength band among bands includingred (R), green (G), and blue (B) emitted from the first light emitting element ED1 and the second light emitting element ED2 to pass through, but the implementations of the disclosure are not limited thereto.

Referring to FIGS. 5 to 12, a support layer 540 may be disposed on the black matrix 340, the first color filter 341, and the second color filter 541. For example, the support layer 540 may include an organic material to protect the black matrix 340, the first color filter 341, and the second color filter 541, but the implementations of the disclosure are not limited thereto.

Referring to FIGS. 5 to 12, the display panel according to implementations of the disclosure may include a first lens 520 overlapping the first opening 342 and the first light emitting element ED1, and a second lens 530 overlapping the second opening 542 and the second light emitting element ED2, disposed between the encapsulation layer 200 and the second planarization layer 336.

For example, the height of each of the first lens 520 and the second lens 530 may be less than the height of the second planarization layer 336, and each of the first lens 520 and the second lens 530 may include a flat rear surface (or lower surface) and a convex upper surface, but the implementations of the disclosure are not limited thereto. For example, it is shown in FIGS. 5 to 12 that each of the first lens 520 and the second lens 530 is formed as a semi-circular shape, but the implementations of the disclosure are not limited thereto, and various other shapes are also possible.

For example, the first lens 520 and the second lens 530 may be a first convex portion and a second convex portion, respectively, but the implementations of the disclosure are not limited thereto.

Referring to FIGS. 5 to 12, the display panel according to implementations of the disclosure may include a first partition wall 510 (also referred to as a partition wall) overlapping the black matrix 340 and disposed on a side surface of the encapsulation layer 200 and/or the second planarization layer 336. For example, the first partition wall 510 may also be referred to as an organic partition wall, but the implementations of the disclosure are not limited thereto. It is to be noted that the formed position of the first partition wall 510 is not limited to those shown in FIGS. 5 to 12. For example, the first partition wall 510 may not be formed on a side surface of the second organic layer 334, or the first partition wall 510 may be formed on a side surface of the first organic layer 332. In addition, the first lens 520 and second lens 530 are formed to converge the light emitted from each subpixel, and may also be omitted when necessary.

For example, the first partition wall 510 may include an organic material including a light absorbing material. As another example, the first partition wall 510 may include an organic material including a light reflecting material, but the implementations of the disclosure are not limited thereto.

For example, the rear surface of each of the first convex portion and the second convex portion may be positioned from the substrate than the rear surface of the organic partition wall, but the implementations of the disclosure are not limited thereto.

Referring to FIGS. 5 to 8, the first partition wall 510 may overlap the black matrix 340 and may be positioned on a side surface of at least one of the second organic layer 334, the third inorganic layer 335, or the second planarization layer 336. For example, the first partition wall 510, the second organic layer 334, and the second planarization layer 336 may include different organic materials, and the third inorganic layer 335 may include an inorganic material, but the implementations of the disclosure are not limited thereto. For example, the first partition wall 510 may separate the second organic layer 334 and/or the second planarization layer 336 into a plurality of portions spaced apart from each other. In addition, the first partition wall 510 may be arranged to surround the emission area of each subpixel, so as to obtain desired viewing angle characteristic.

Referring to FIG. 5, the first partition wall 510 may be positioned on a side surface of the second organic layer 334. The rear surface of the first partition wall 510 may contact the upper surface of a second inorganic layer 333, and the upper surface of the first partition wall 510 may contact the rear surface of the third inorganic layer 335. For example, the height of the first partition wall 510 may include a height smaller than the height of each of the first lens 520 and the second lens 530, but the implementations of the disclosure are not limited thereto.

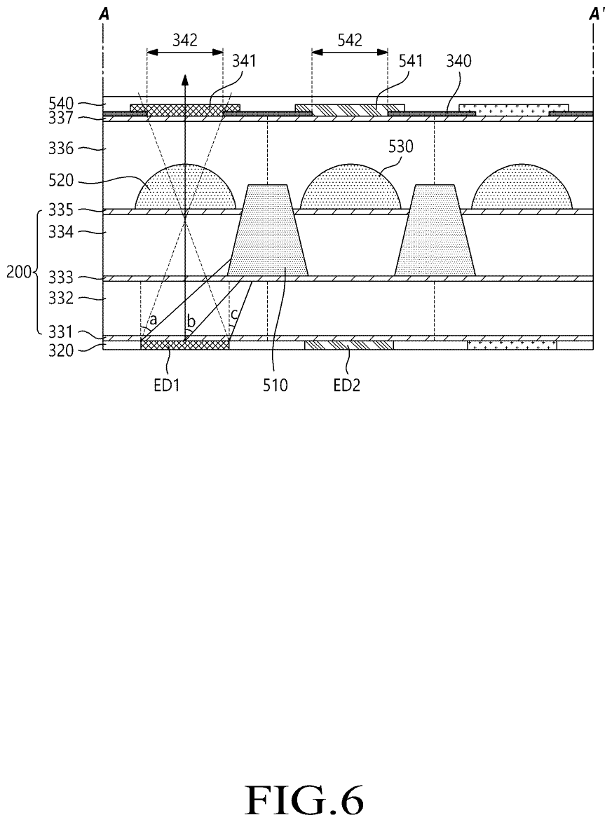

Referring to FIG. 6, the first partition wall 510 may be positioned on a side surface of at least one of the second organic layer 334, the third inorganic layer 335, or the second planarization layer 336. The rear surface of the first partition wall 510 may contact the upper surface of the second inorganic layer 333, and the second planarization layer 336 may be disposed to extend between the upper surface of the first partition wall 510 and the black matrix 340 from the side surface of the first partition wall 510. For example, the height of the first partition wall 510 may include a height smaller than the height of each of the first lens 520 and the second lens 530, but the implementations of the disclosure are not limited thereto.

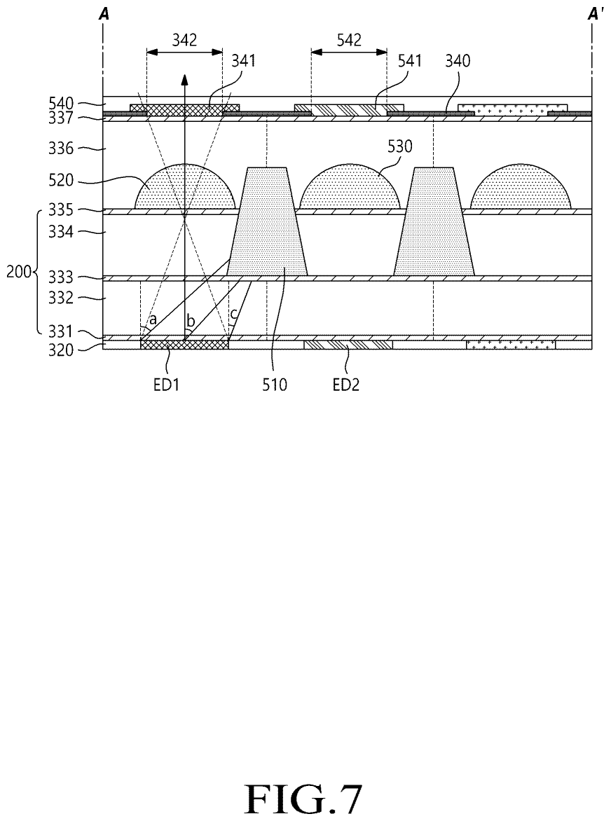

Referring to FIG. 7, the first partition wall 510 may be positioned on a side surface of at least one of the second organic layer 334, the third inorganic layer 335, or the second planarization layer 336. The rear surface of the first partition wall 510 may contact the upper surface of the second inorganic layer 333, and the second planarization layer 336 may be disposed to extend between the upper surface of the first partition wall 510 and the black matrix 340 from the side surface of the first partition wall 510. For example, the height of the first partition wall 510 may include a height corresponding to the height of each of the first lens 520 and the second lens 530, but the implementations of the disclosure are not limited thereto.

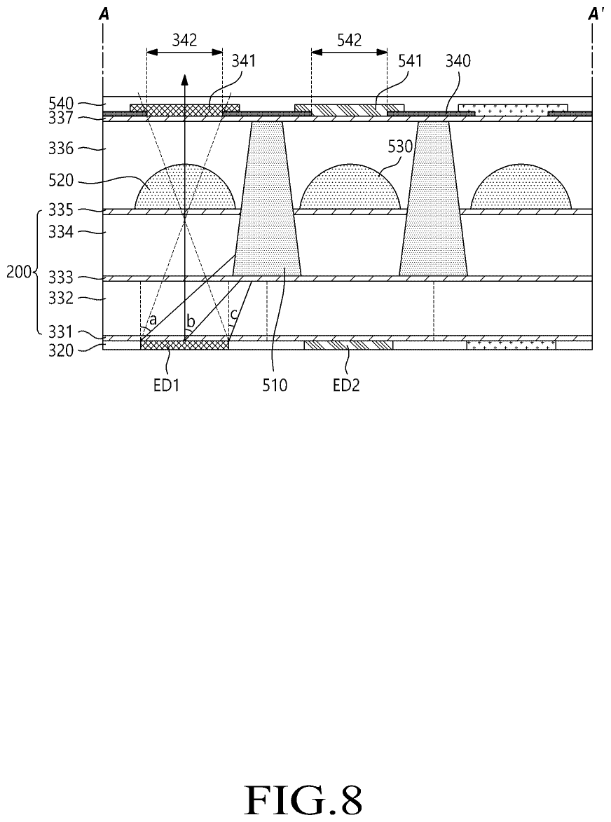

Referring to FIG. 8, the first partition wall 510 may be positioned on a side surface of at least one of the second organic layer 334, the third inorganic layer 335, or the second planarization layer 336. The rear surface of the first partition wall 510 may contact the upper surface of the second inorganic layer 333, and the upper surface of the first partition wall 510 may contact the rear surface of the fourth inorganic layer 337. For example, the height of the first partition wall 510 may include a height larger than the height of each of the first lens 520 and the second lens 530, but implementations of the disclosure are not limited thereto.

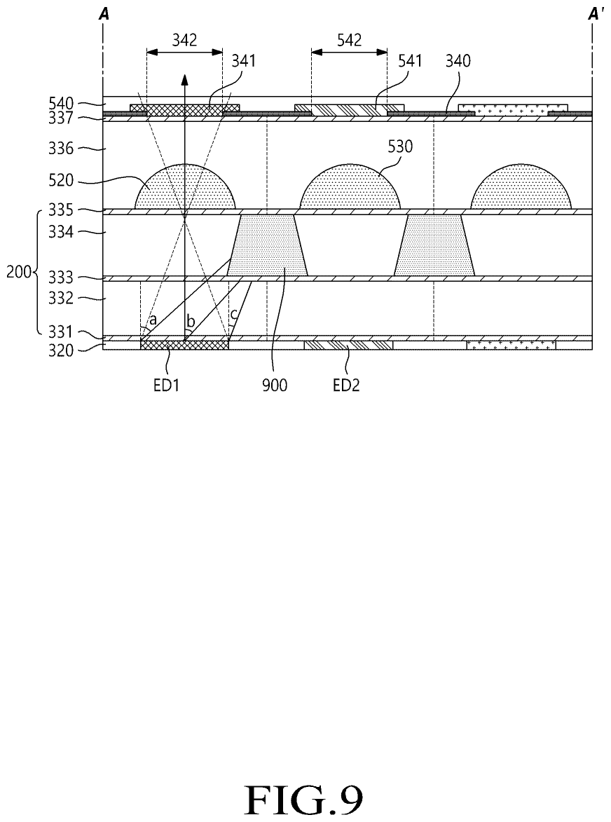

Referring to FIGS. 9 to 12, the first partition wall 510 may include a lower partition wall 900 and an upper partition wall 1000 at a position overlapping a black matrix 340. The lower partition wall 900 may be positioned on a side surface of the second organic layer 334, and the upper partition wall 1000 may be positioned on a side surface of the second planarization layer 336. The lower partition wall 900, the upper partition wall 1000, the second organic layer 334, and the second planarization layer 336 may include different organic materials. For example, the first partition wall 510, the lower partition wall 900, and the upper partition wall 1000 may also be referred to as organic partition walls, but implementations of the disclosure are not limited thereto.

Referring to FIG. 9, the lower partition wall 900 may be positioned on a side surface of the second organic layer 334. The rear surface of the lower partition wall 900 may contact the upper surface of the second inorganic layer 333, and the upper surface of the lower partition wall 900 may contact the rear surface of the third inorganic layer 335. For example, the height of the lower partition wall 900 may include a height smaller than the height of each of the first lens 520 and the second lens 530, but implementations of the disclosure are not limited thereto.

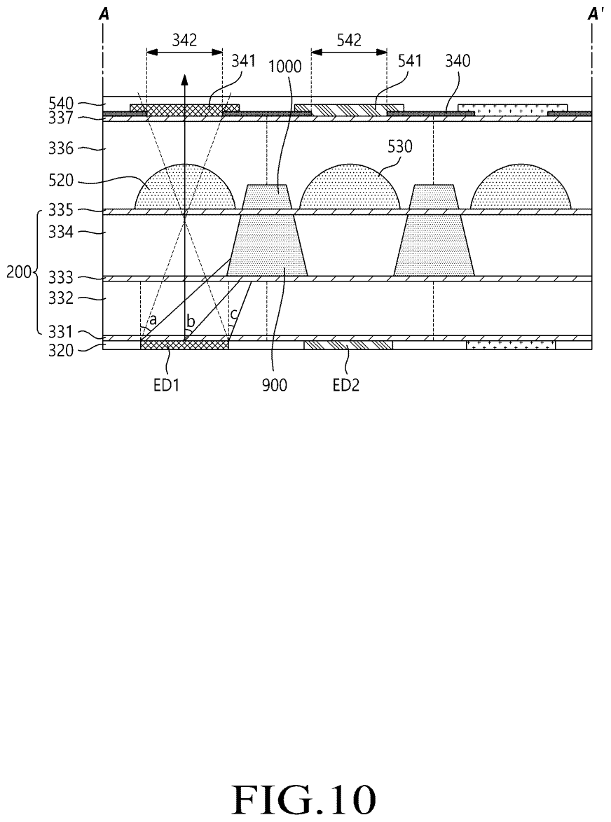

Referring to FIG. 10, the lower partition wall 900 may be positioned on a side surface of the second organic layer 334. The rear surface of the lower partition wall 900 may contact the upper surface of the second inorganic layer 333, and the upper surface of the lower partition wall 900 may contact the rear surface of the third inorganic layer 335. The second planarization layer 336 may be disposed to extend over a side surface of the upper partition wall 1000 between the upper surface of the upper partition wall 1000 and the black matrix 340. For example, the height of the upper partition wall 1000 may include a height smaller than the height of each of the first lens 520 and the second lens 530, but implementations of the disclosure are not limited thereto.

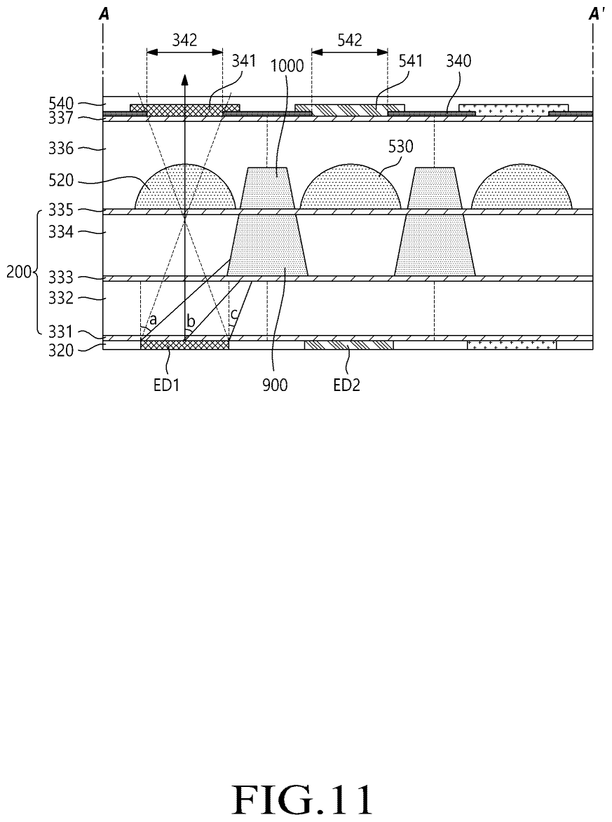

Referring to FIG. 11, the lower partition wall 900 may be positioned on a side surface of the second organic layer 334. The rear surface of the lower partition wall 900 may contact the upper surface of the second inorganic layer 333, and the upper surface of the lower partition wall 900 may contact the rear surface of the third inorganic layer 335. The second planarization layer 336 may be disposed to extend over a side surface of the upper partition wall 1000 between the upper surface of the upper partition wall 1000 and the black matrix 340. For example, the height of the upper partition wall 1000 may include a height corresponding to the height of each of the first lens 520 and the second lens 530, but implementations of the disclosure are not limited thereto.

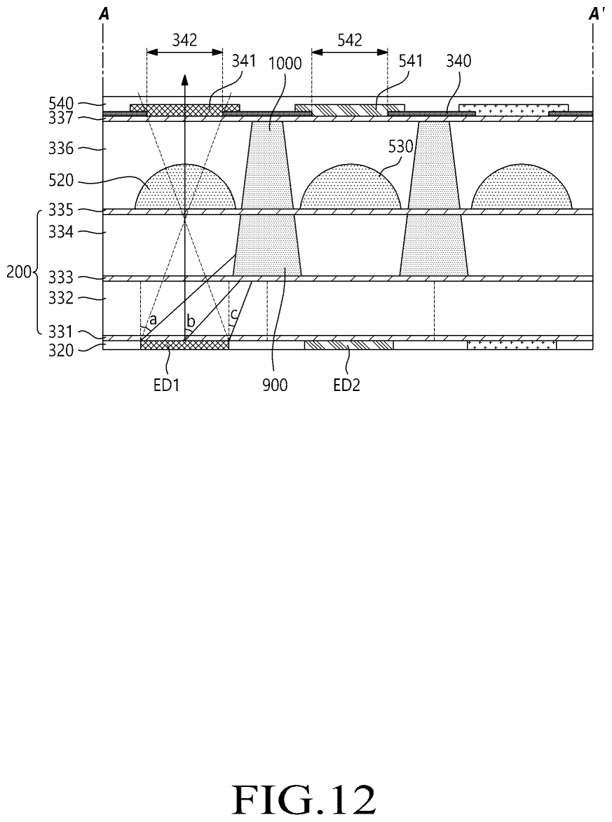

Referring to FIG. 12, the lower partition wall 900 may be positioned on a side surface of the second organic layer 334. The rear surface of the lower partition wall 900 may contact the upper surface of the second inorganic layer 333, and the upper surface of the lower partition wall 900 may contact the rear surface of the third inorganic layer 335. The rear surface of the upper partition wall 1000 may contact the upper surface of the third inorganic layer 335, and the upper surface of the upper partition wall 1000 may contact the rear surface of the fourth inorganic layer 337. For example, the height of the upper partition wall 1000 may include a height larger than the height of each of the first lens 520 and the second lens 530, but implementations of the disclosure are not limited thereto.

Referring to FIGS. 5 to 12, first light may be emitted from a first light emitting element ED1 at any angle including angles a, b, and c. Angles a, b, and c may include at least one of 30°, 45°, or 60°. For example, angle a may be 30°, angle b may be 45°, and angle c may be 60°, but implementations of the disclosure are not limited thereto.

For example, when the first light emitted from the first light emitting element ED1 at any angle including angles a, b, and c passes through the second color filter 542, an overlap of wavelength bands may occur. For example, the first partition wall 510 may reflect the light of the overlapping wavelength bands. As another example, the first partition wall 510 may absorb the light of the overlapping wavelength bands, but implementations of the disclosure are not limited thereto.

When the display device 100 according to implementations of the disclosure described above is implemented as a vehicle display, a smartphone, or an AR/VR device, a narrow viewing angle may be achieved so that an image provided to the user is not recognized by surrounding people. For example, the display device may limit the direction of light emitted from each light emitting element using a light control film (LCF) including a light blocking pattern on an upper portion of the display panel. However, the use of the light control film may lead to an increase in the display panel's thickness, a decrease in its flexibility, and a rise in process costs.

Accordingly, according to a viewing angle characteristic enhancement structure according to implementations of the disclosure described above, when the display device 100 is implemented as a vehicle display, a smartphone, or an AR/VR device, the screen may be clearly visible from the front of the display device 100, but not from a side surface of the display device 100. In other words, according to the viewing angle characteristic enhancement structure according to implementations of the disclosure, narrow viewing angle characteristics may be enhanced.

Further, according to the viewing angle characteristic enhancement structure according to implementations of the disclosure, light emitted from the light emitting element of each subpixel may be emitted to the outside of the display panel 110 without being lost inside the display panel. In other words, according to the viewing angle characteristic enhancement structure according to implementations of the disclosure, light extraction may be enhanced.

Further, according to the viewing angle characteristic enhancement structure according to implementations of the disclosure, by assisting the light emitted from the light emitting element of each subpixel to advance forward, it may also help to prevent or reduce color mixing between two adjacent subpixels.

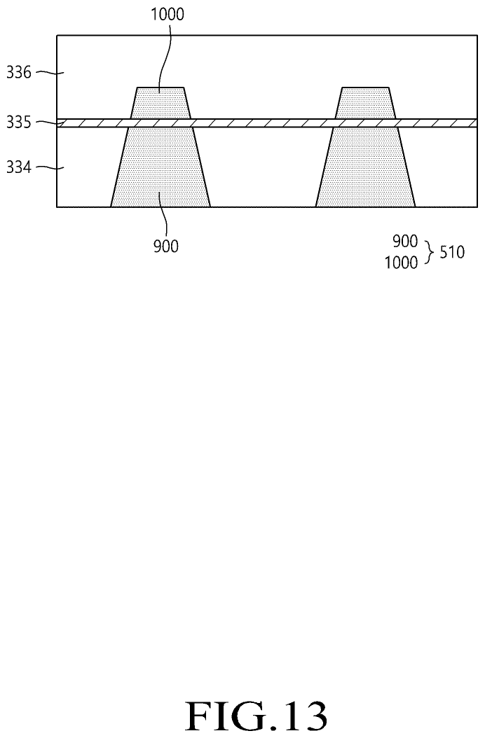

FIGS. 13 to 16 are diagrams illustrating a structure of a lower partition wall 900 and an upper partition wall 1000 of a display panel according to implementations of the disclosure.

Referring to FIG. 13, the side surfaces of the lower partition wall 900 and the upper partition wall 1000 may include a positive taper shape. For example, the angle formed by the side surface and the rear surface of the lower partition wall 900 may include an acute angle. As another example, the angle formed by the side surface and the rear surface of the upper partition wall 1000 may include an acute angle, but the implementations of the disclosure are not limited thereto.

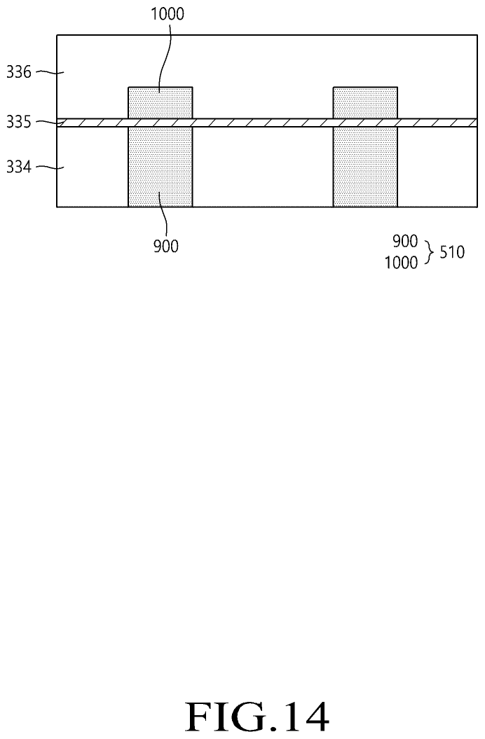

Referring to FIG. 14, the angle formed by the side surface and the rear surface of the lower partition wall 900 and the upper partition wall 1000 may include a right angle. For example, the angle formed by the side surface and the rear surface of the lower partition wall 900 may include a right angle. As another example, the angle formed by the side surface and the rear surface of the upper partition wall 1000 may include a right angle, but the implementations of the disclosure are not limited thereto.

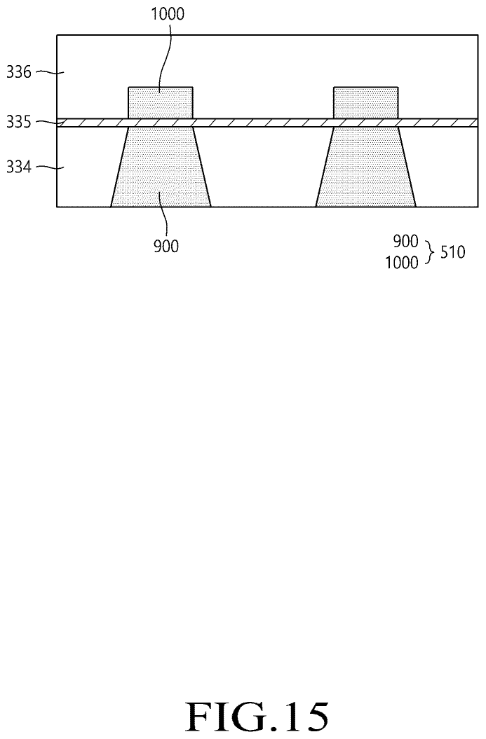

Referring to FIG. 15, one of the side surface of the lower partition wall 900 and the side surface of the upper partition wall 1000 may include a positive taper shape, and the other may include a shape different from the positive taper shape. For example, the angle formed by the side surface and the rear surface of the lower partition wall 900 may include an acute angle. As another example, the angle formed by the side surface and the rear surface of the upper partition wall 1000 may include a right angle, but the implementations of the disclosure are not limited thereto.

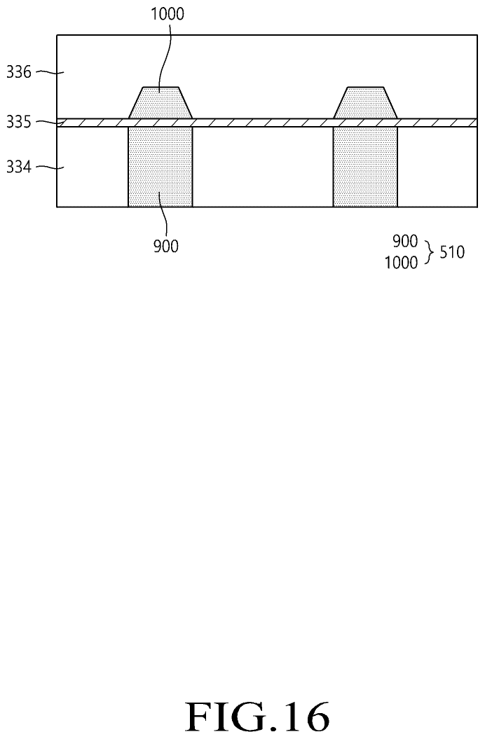

Referring to FIG. 16, one of the side surface of the lower partition wall 900 and the side surface of the upper partition wall 1000 may include a positive taper shape, and the other may include a shape different from the positive taper shape. For example, the angle formed by the side surface and the rear surface of the lower partition wall 900 may include a right angle. As another example, the angle formed by the side surface and the rear surface of the upper partition wall 1000 may include an acute angle, but the implementations of the disclosure are not limited thereto.

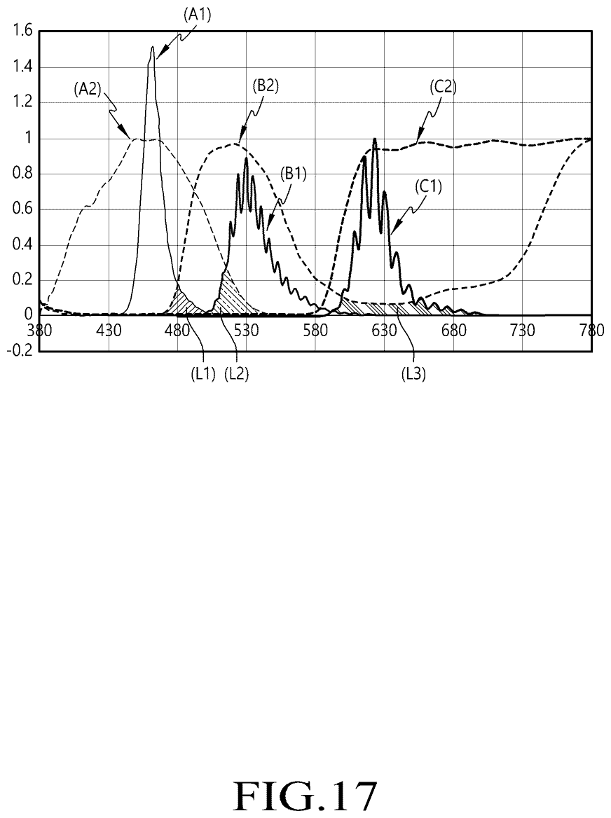

FIGS. 17 to 20 illustrate an example of a graph according to implementations of the disclosure. For example, a first light emitting element may emit first light including a first wavelength band, a second light emitting element may emit second light including a second wavelength band, and a third light emitting element may emit third light including a third wavelength band. As another example, the first wavelength band may be shorter than the second wavelength band, and the second wavelength band may be shorter than the third wavelength band, but the implementations of the disclosure are not limited thereto.

For example, one of the first light, the second light, and the third light may be one of red (R), green (G), and blue (B) colors, and another may be selected from among red (R), green (G), and blue (B) colors, and the other may include one of red (R), green (G), and blue (B) colors. For example, if the first light includes blue (B) color light, the second light may include green (G) color light, and the third light may include red (R) color light. Implementations of the disclosure are not limited thereto.

FIG. 17 is an illustration of an example of the spectrum according to the wavelength band according to implementations of the disclosure. The X-axis denotes the wavelength band of the light, and the Y-axis denotes the spectrum of the light. A1 is the emission spectrum of the first light emitted from the first light emitting element, and A2 is the transmission spectrum when the first light passes through the first color filter. B1 is the emission spectrum of the second light emitted from the second light emitting element, and B2 is the transmission spectrum when the second light passes through the second color filter. C1 is the emission spectrum of the third light emitted from the third light emitting element, and C2 is the transmission spectrum when the third light passes through the third color filter.

Referring to FIG. 17, it is identified that light leakage occurs in the wavelength band L1 where A1 and B2 overlap, the wavelength band L2 where B1 and A2 overlap, and the wavelength band L3 where C1 and B2 overlap.

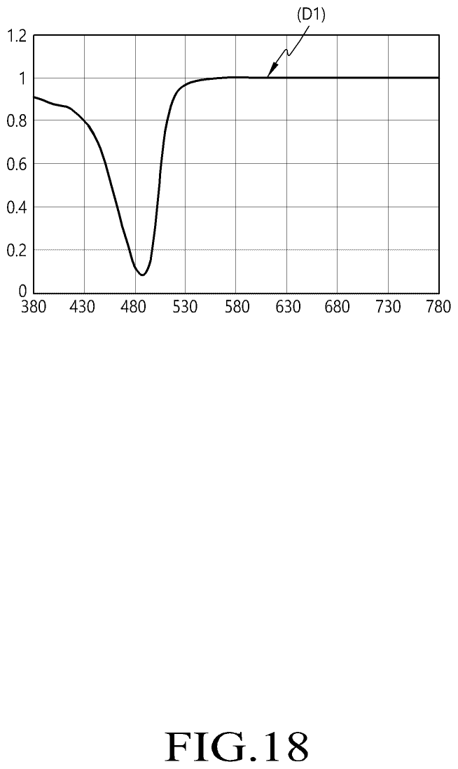

FIG. 18 is an illustration of an example of the spectrum according to the application of a first partition wall according to implementations of the disclosure. The X-axis denotes the wavelength band of the light, and the Y-axis denotes the spectrum of the first partition wall (which may also be referred to as the light intensity). D1 is the absorption or reflection spectrum of the first partition wall.

Referring to FIG. 18, referring to D1 according to the structure in which the first partition wall according to implementations of the disclosure is applied, it may be identified that light in the wavelength band corresponding to the overlapping area of the first wavelength band and the second wavelength band (corresponding to L1 in FIG. 17) is absorbed (or reflected). Accordingly, light leakage in the overlapping area of the first wavelength band and the second wavelength band may be prevented or reduced.

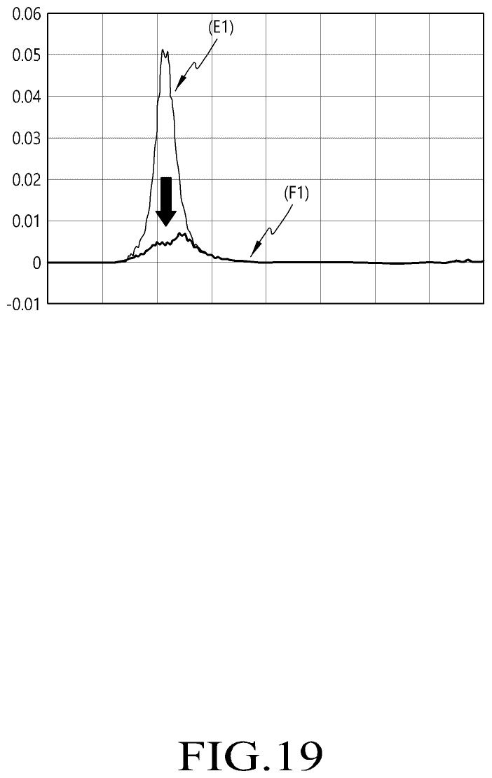

FIG. 19 is an illustration of an example of the optical spectrum before and after the application of a first partition wall according to implementations of the disclosure. The X-axis denotes the wavelength band of the light, and the Y-axis denotes the spectrum of the leaked light. E1 is the spectrum of the leaking light according to the wavelength band before the application of the first partition wall, and F1 is the spectrum of the leaking light according to the wavelength band after the application of the first partition wall.

Referring to FIG. 19, E1 and F1 denote the graphs of leaking light in the wavelength band of the area (corresponding to L1 of FIG. 17) where the first wavelength band and the second wavelength band overlap before and after application of the first partition wall according to implementations of the disclosure. It is identified that the leaking light of F1 relative to E1 is reduced by 75% or more.

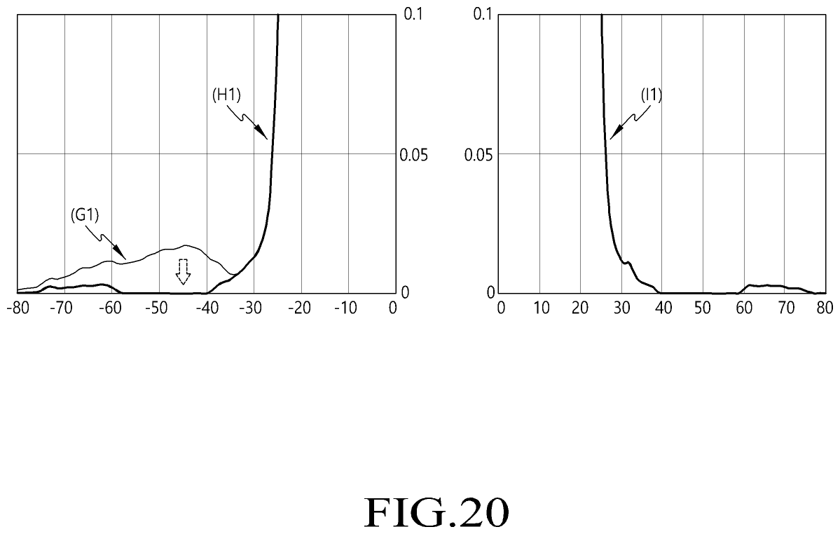

FIG. 20 is an illustration of an example of the cut-off ratio according to the viewing angle before and after the application of a first partition wall according to implementations of the disclosure. The X-axis denotes the viewing angle (°) of light, and the Y-axis denotes the intensity of light. G1 is the graph of light intensity according to the viewing angle before the application of the first partition wall, and H1 and I1 are the graphs of light intensity according to the viewing angle after the application of the first partition wall. The cut-off ratio denotes the maximum value of the ratio relative to frontal luminance at a specific angle.

Referring to FIG. 20, G1 exhibited light leakage at angles of −30° or more, but H1 and I1, which are structures with the first partition wall applied, exhibited a characteristic of enhanced cut-off ratio as the leaking light was absorbed or blocked by the first partition wall at all angles.

Implementations of the disclosure described above are briefly described below.

A display panel according to implementations of the disclosure may include a substrate and a first light emitting element disposed on the substrate, and may include a second light emitting element disposed on the substrate and adjacent to the first light emitting element.

An encapsulation layer may be disposed on the first and second light emitting elements, and a planarization layer may be disposed on the encapsulation layer.

A black matrix may be disposed on the planarization layer and may include a first opening and a second opening.

A first lens overlapping the first opening may be disposed between the encapsulation layer and the planarization layer, and a second lens overlapping the second opening may be disposed between the encapsulation layer and the planarization layer.

A first color filter may be disposed on the black matrix and overlap the first opening, and a second color filter may be disposed on the black matrix and overlap the second opening corresponding to the first and second light emitting elements respectively.

A partition wall may overlap the black matrix and may be disposed on a side surface of at least one of the encapsulation layer or the planarization layer.

A height of each of the first lens and the second lens may be less than a height of the planarization layer.

Each of the first lens and the second lens may include a flat lower surface and a convex upper surface.

The encapsulation layer may include a first inorganic layer disposed on the first light emitting element and the second light emitting element. A first organic layer may be disposed on the first inorganic layer, a second inorganic layer may be disposed on the first organic layer, a second organic layer may be disposed on the second inorganic layer, and a third inorganic layer may be disposed on the second organic layer.

The partition wall may be positioned on a side surface of the second organic layer. The partition wall may include a lower partition wall positioned on a side surface of the second organic layer and an upper partition wall positioned on a side surface of the planarization layer (corresponding to the above-described second planarization layer 336).

A lower surface of the lower partition wall may contact an upper surface of the second inorganic layer, and an upper surface of the lower partition wall may contact a lower surface of the third inorganic layer.

A lower surface of the upper partition wall may contact an upper surface of the third inorganic layer, and the second planarization layer may be disposed to extend between the upper surface of the upper partition wall and the black matrix from a side surface of the upper wall partition.

The upper partition wall may have a height smaller than a height of each of the first lens and the second lens.

The upper partition wall may have a height corresponding to the height of each of the first lens and the second lens.

The upper partition wall may have a height larger than the height of each of the first lens and the second lens.

A fourth inorganic layer may be further included between the second planarization layer and the black matrix, and the lower surface of the upper partition wall may contact the upper surface of the third inorganic layer, and the upper surface of the upper partition wall may contact the lower surface of the fourth inorganic layer.

A side surface of the lower partition wall and a side surface of the upper partition wall may include a positive taper shape.

One of the side surface of the lower partition wall and the side surface of the upper partition wall may include a positive taper shape, and the other may include a shape different from the positive taper shape.

The angle formed by the side surface and the lower surface of the partition wall may have an acute angle.

The angle formed by the side surface and the lower surface of the partition wall may have a right angle.

The partition wall may include an organic material different from an organic material included in the encapsulation layer.

The partition wall may include an organic material including a light absorbing material.

The partition wall may include an organic material including a light reflecting material.

First light emitted from the first light emitting element may include a first wavelength band, the second color filter may transmit a second light having a second wavelength band longer than the first wavelength band, and the partition wall may absorb light in a wavelength band where the first wavelength band and the second wavelength band overlap.

The first light emitted from the first light emitting element may include a first wavelength band, the second color filter may transmit second light having a second wavelength band longer than the first wavelength band, and the partition wall may reflect light in a wavelength band where the first wavelength band and the second wavelength band overlap.

The partition wall may surround each of the first and second openings.

A display panel according to implementations of the disclosure may include a substrate and a first light emitting element disposed on the substrate, and may include a second light emitting element disposed on the substrate and adjacent to the first light emitting element.

A bank disposed between the first light emitting element and the second light emitting element, and a black matrix disposed on the first light emitting element and the second light emitting element and including a first opening and a second opening may be included.

A first color filter overlapping the first opening and a second color filter overlapping the second opening and disposed on the black matrix may be included.

A first convex portion disposed between the first light emitting element and the first color filter, overlapping the first opening and having a convex upper surface, and a second convex portion disposed between the second light emitting element and the second color filter, overlapping the second opening and having a convex upper surface, may be included.

An organic partition wall disposed between the bank and the black matrix and including an organic material, may be included.

The lower surface of each of the first convex portion and the second convex portion may be positioned further from the substrate than the lower surface of the organic partition wall.

An encapsulation layer disposed between the first light emitting element and the second light emitting element, and the first color filter and the second color filter, may be included, and the encapsulation layer may include a plurality of organic layers and inorganic layers interleaved within each other. The plurality of organic layers include a first organic material, and the organic partition wall may include a second organic material different from the first organic material.

The second organic material may include a higher light absorbance than a light absorbance of the first organic material.

The second organic material may include a higher light reflectance than a light reflectance of the first organic material.

According to implementations of the disclosure described above, there may be provided a display device having a structure capable of implementing the desired viewing angle characteristics through a partition wall structure.

According to implementations of the disclosure, there may be provided a display device having a structure that facilitates the implementation of the desired viewing angle characteristics through a lens structure.

According to implementations of the disclosure, there may be provided a display device having a structure capable of implementing viewing angle characteristics in the display panel without attaching a separate film for implementing the desired viewing angle characteristics to the display panel.

According to implementations of the disclosure, it may be possible to control the viewing angle characteristics in the desired form without a film attachment process, enabling process optimization.

According to implementations of the disclosure, as the desired viewing angle characteristics may be achieved without an external film, the flexibility of the display panel may be enhanced, and the thickness may be decreased.

The organic partition wall may be disposed between the first convex portion and the second convex portion.

The above description has been presented to enable any person skilled in the art to make and use the technical idea of the disclosure, and has been provided in the context of a particular application and its requirements. Various modifications, additions and substitutions to the described implementations will be readily apparent to those skilled in the art, and the general principles defined herein may be applied to other implementations and applications without departing from the spirit and scope of the disclosure. The above description and the accompanying drawings provide an example of the technical idea of the disclosure for illustrative purposes only. For example, the disclosed implementations are intended to illustrate the scope of the technical idea of the disclosure.

What is claimed is:

1. A display device comprising:
a substrate;
first light emitting elements and second light emitting elements disposed on the substrate and adjacent to each other;
an encapsulation layer disposed on the first light emitting elements and the second light emitting elements;
a planarization layer disposed on the encapsulation layer;
a black matrix disposed on the planarization layer and including a first opening and a second opening corresponding to the first light emitting elements and the second light emitting elements, respectively; and
a partition wall overlapping the black matrix and disposed on a side surface of at least one of the encapsulation layer or the planarization layer.

2. The display device of claim 1, comprising:
a first lens disposed between the encapsulation layer and the planarization layer, the first lens overlapping the first opening; and
a second lens disposed between the encapsulation layer and the planarization layer, the second lens overlapping the second opening.

3. The display device of claim 2,
wherein a height of each of the first lens and the second lens is less than a height of the planarization layer.

4. The display device of claim 2, wherein each of the first lens and the second lens includes a flat lower surface and a convex upper surface.

5. The display device of claim 2, wherein the encapsulation layer includes:
a first inorganic layer disposed on the first light emitting element and the second light emitting element;
a first organic layer disposed on the first inorganic layer;
a second inorganic layer disposed on the first organic layer;
a second organic layer disposed on the second inorganic layer; and
a third inorganic layer disposed on the second organic layer, and
wherein the partition wall is positioned on a side surface of the second organic layer.

6. The display device of claim 5, wherein the partition wall includes:
a lower partition wall positioned on a side surface of the second organic layer; and
an upper partition wall positioned on a side surface of the planarization layer.

7. The display device of claim 6, wherein a lower surface of the lower partition wall contacts an upper surface of the second inorganic layer, and an upper surface of the lower partition wall contacts a lower surface of the third inorganic layer.

8. The display device of claim 6, wherein a lower surface of the upper partition wall contacts an upper surface of the third inorganic layer, and
wherein the planarization layer is disposed to extend over a side surface of the upper partition wall between an upper surface of the upper partition wall and the black matrix.

9. The display device of claim 6, wherein the upper partition wall has a height smaller than a height of each of the first lens and the second lens.

10. The display device of claim 6, wherein the upper partition wall has a height corresponding to a height of each of the first lens and the second lens.

11. The display device of claim 6, wherein the upper partition wall has a height larger than a height of each of the first lens and the second lens.

12. The display device of claim 6, comprising a fourth inorganic layer between the planarization layer and the black matrix,
wherein a lower surface of the upper partition wall contacts an upper surface of the third inorganic layer, and
wherein an upper surface of the upper partition wall contacts a lower surface of the fourth inorganic layer.

13. The display device of claim 6, wherein a side surface of the lower partition wall and a side surface of the upper partition wall have a positive taper shape.

14. The display device of claim 6, wherein one of a side surface of the lower partition wall and a side surface of the upper partition wall has a positive taper shape, and the other has a shape different from the positive taper shape.

15. The display device of claim 1, wherein an angle formed between a side surface and a lower surface of the partition wall is an acute angle.

16. The display device of claim 1, wherein an angle formed between a side surface and a lower surface of the partition wall is a right angle.

17. The display device of claim 1, wherein the partition wall includes an organic material different from the organic material included in the encapsulation layer.

18. The display device of claim 1, wherein the partition wall includes an organic material including a light absorbing material.

19. The display device of claim 1, wherein the partition wall includes an organic material including a light reflecting material.

20. The display device of claim 1, comprising:
a first color filter disposed on the black matrix and overlapping the first opening; and
a second color filter disposed on the black matrix and overlapping the second opening.

21. The display device of claim 20, wherein first light emitted from the first light emitting element includes a first wavelength band,
wherein the second color filter transmits second light having a second wavelength band longer than the first wavelength band, and
wherein the partition wall absorbs light in a wavelength band in which the first wavelength band and the second wavelength band overlap.

22. The display device of claim 20, wherein first light emitted from the first light emitting element includes a first wavelength band,
wherein the second color filter transmits second light having a second wavelength band longer than the first wavelength band, and
wherein the partition wall reflects light in a wavelength band in which the first wavelength band and the second wavelength band overlap.

23. The display device of claim 1, wherein the partition wall surrounds each of the first and second openings.

24. A display device, comprising:
a substrate;
first light emitting elements and second light emitting elements disposed on the substrate and adjacent to each other;
a bank disposed between the first light emitting elements and the second light emitting elements;
a black matrix disposed on the first light emitting elements and the second light emitting elements and including a first opening and a second opening;
a first color filter disposed on the black matrix and overlapping the first opening;
a second color filter disposed on the black matrix and overlapping the second opening;
a first convex portion disposed between the first light emitting element and the first color filter, wherein the first convex portion overlaps the first opening, and wherein the first convex portion has a convex upper surface;
a second convex portion disposed between the second light emitting element and the second color filter, wherein the second convex portion overlaps the second opening, and wherein the first convex portion has a convex upper surface; and
an organic partition wall disposed between the bank and the black matrix and including an organic material.

25. The display device of claim 24, wherein a lower surface of each of the first convex portion and the second convex portion is positioned farther from the substrate than a lower surface of the organic partition wall.

26. The display device of claim 24, comprising an encapsulation layer disposed between (i) the first light emitting element and the second light emitting element and (ii) the first color filter and the second color filter,
wherein the encapsulation layer includes a plurality of organic layers and a plurality of inorganic layers interleaved within each other,
wherein the plurality of organic layers include a first organic material, and
wherein the organic partition wall includes a second organic material different from the first organic material.

27. The display device of claim 26, wherein the second organic material has a higher light absorbance than a light absorbance of the first organic material.

28. The display device of claim 27, wherein the second organic material has a higher light reflectance than a light reflectance of the first organic material.

29. The display device of claim 24, wherein the organic partition wall is disposed between the first convex portion and the second convex portion.
